(19) United States
(12) Patent Application Publication
(10) Pub. No.: US 2024/0175935 A1
(43) Pub. Date: May 30, 2024

(54) METHOD FOR DETERMINING THE AGING OF A BATTERY STORAGE DEVICE, APPARATUS, AND COMPUTER PROGRAM PRODUCT

(71) Applicant: Siemens Aktiengesellschaft, München (DE)

(72) Inventors: Barbara Schricker, Erlangen (DE); Arno Arzberger, Stegaurach (DE); Kilian Scheer, Bad Staffelstein (DE)

(21) Appl. No.: 18/512,684

(22) Filed: Nov. 17, 2023

(30) Foreign Application Priority Data
Nov. 24, 2022 (EP) 22209399.9

(51) Int. Cl. G01R 31/392; G01R 31/374; G01R 31/3835

(52) U.S. Cl. CPC G01R 31/392; G01R 31/374; G01R 31/3835

(57) ABSTRACT

A method including a) running through at least two cycles of a cycling process for measuring parameters within the cycles in the temporally first phase, b) manipulating measurement data formed by the parameters measured over the cycles in a second phase in such a way that at least one part of the measurement data from at least one part of the cycles is changed within the cycles with respect to parameters at least partially correlating with an upper voltage limit and a lower voltage limit, c) forming a generated measurement data set for the part of the cycles in such a way that modified at least partially correlating parameters of the manipulated part of the measurement data and the unmanipulated part of the measurement data from the part of the cycles are merged, d) generating signals representing the values of the generated measurement data, e) determining the aging.

### CROSS-REFERENCE TO RELATED APPLICATIONS

This application claims priority to EP Application No. 22209399.9, having a filing date of Nov. 24, 2022, the entire contents of which are hereby incorporated by reference.

### FIELD OF TECHNOLOGY

The following relates to a method for determining the aging of a battery storage device, to an apparatus for carrying out the method and to a computer program product.

### BACKGROUND

Lithium-ion rechargeable batteries, also referred to as lithium-ion batteries below, are used as energy stores in mobile and stationary applications on account of their high power and energy density. In order to be able to operate these electrochemical energy stores safely, reliably and for as long as possible without maintenance, knowledge of critical operating states, in particular with respect to the state of charge (SOC) and with respect to the state of health (SOH), that is as accurate as possible is necessary.

It is known that the aging of a battery, in particular what is known as the cyclic aging, can be negatively affected by high temperatures and rapid charging at low temperatures, depending on the state of charge, the depth of discharge, and the charging power and the discharge power. It is therefore possible that the same type of battery cell can handle a different large number of load cycles depending on the specified parameters.

In order to determine the expected aging process, an aging characteristic of the battery cell used is determined in the prior art by means of measurements during the design phase of a battery system. The real aging rate with real load profiles is often not tested. Rather, the aging rate, or the cycle stability, is determined on compressed load profiles in so-called RAFF tests. These results are used to parameterize empirical aging models which show the aging process in the application. A future aging process determined on the basis of physical and/or chemical measurements depending the load profile, the operating point and the ambient conditions is difficult to carry out due to the non-linearity of the underlying physical and chemical processes and their complex interactions.

Predicting the state of health of a battery is unfavorably complex. The parameterization of a meaningful aging model is therefore often unfavorably very time-consuming. Furthermore, assumptions often have to be made to assess the aging, which disadvantageously render said assessment inaccurate.

This has the detrimental effect that battery storage devices are dimensioned to be larger than the performance and lifetime requirements require, in order to ensure sufficient power and thus to be able to comply with liability and warranty commitments.
According to the prior art, the aging of electrochemical energy stores, in particular Li-ion batteries, branches into two fundamentally distinguishable branches.
Behind the branch of “cyclic” aging is the observation that Li-ion batteries lose part of their storage capacity for electrical charge with each load cycle. The speed at which the so-called residual capacity decreases depends on the load profile, the operating point and the ambient conditions of the battery.
For the measurement of cyclic aging, a repeated change from checkup tests and the so-called cycling takes place according to the prior art. During cycling, so-called cycle profiles are periodically applied to the cells under different environmental conditions (e.g. temperature, pressure, etc.). The cycle profiles used may be current profiles or power profiles, less commonly voltage profiles. The typical variables for defining the profiles that are run through periodically during cycling include in particular current intensity (C-rate), electrical power (CP-rate), mean state of charge (SOC) and/or depth of discharge (DOD).
Behind the branch of “calendar” aging is the observation that Li-ion batteries age even when they are not used (charged and discharged) at all.
Calendar aging is measured according to the prior art in so-called storage tests. In this case, the cells are stored at different combinations of storage temperature and state of charge (SOC). Storage is effected either with open terminals or, using a potentiostat, at a constant voltage.
In order to determine the aging rate, a so-called checkup test performed for both branches at regular intervals of time. The so-called residual capacity of the cell, i.e. the maximum amount of charge that can be removed under standard conditions, is measured. The aging rate, e.g. for design purposes, is then calculated from the progression of the results.
The results are also the basis for parameterizing empirical aging models. All of the results are approximated to a model therein by a mathematical optimizer.

In order to reduce the complexity or other problems mentioned above, methods are known in which the aging behavior of an energy storage device can be determined in a short period of time.

This includes the subject matter of the post-published German patent application 10 2022 201 676.9, in which, in order to solve these disadvantages, a method for measuring the aging of a battery storage device by means of high-precision coulometry (HPC) is disclosed, wherein the battery storage device should be understood there as meaning in particular a lithium-ion rechargeable battery or a lithium-ion battery which is exposed in particular to cyclic and calendar aging, which reduces its maximum usable capacity over the lifetime of the battery storage device. In the method, a sequence comprising a plurality of load patterns is provided. Each load pattern comprises a multiplicity of discharge and charging processes, each with defined depths of discharge (DOD), characteristic mean states of charge (SOC), current intensities, pause times and/or temperatures.

According to the method, the sequence of the plurality of load patterns is run through in a first step, wherein capacity losses (ΔKap) caused by the discharge and charging processes are measured. Furthermore, the residual capacity of the battery storage device is determined in a second step of the method.

This means that an approach that is based on the “High Power Cycling” method and is improved compared to the prior art is known. In this method, however, in order to be able to determine aging rates from measurement data, the underlying data must generally meet certain requirements.

In particular, the data must have a high degree of measurement accuracy, for example a high degree of measurement accuracy with regard to the time, voltage, current and temperature, and ideally must have been generated according to a special measurement procedure.

This ideal measurement procedure requires the cycling of battery cells. Cycling means repeated charging and discharging alternately over a relatively long period of time and within two fixed voltage limits. The charging current, discharge current and ambient temperature must be kept constant.

It is therefore also a disadvantage that, depending on the hardware used, for example in battery production, where high-priced laboratory equipment is not used, it is often difficult in practice to comply with the required measurement accuracy and to exclude disturbing environmental influences, with the result that the described requirements for the measurement data are not always met.

In the case of the HPC method, an attempt is therefore made, when recording the measured values, to keep the ambient conditions ideal by means of appropriate hardware and the complex experiment, in order to be able to adhere to a special measurement procedure precisely, so that the data obtained can be evaluated directly with the HPC analysis method.

### SUMMARY

An aspect therefore relates to specify a technical solution that solves the disadvantages of the prior art, in particular to realize a simple and reliable method for determining states of health of a rechargeable battery.

The method according to embodiments of the invention for determining the aging of a battery storage device comprises a plurality of steps:
a) running through at least two cycles of a cycling process for determining states, in particular the aging, of the battery storage device for the purpose of measuring parameters within the cycles in the temporally first phase,
b) manipulating measurement data formed by the parameters measured over the cycles in a second phase in such a way that at least one part of the measurement data from at least one part of the cycles is changed within the cycles with respect to parameters at least partially correlating with an upper voltage limit and a lower voltage limit, in particular the upper voltage limit and lower voltage limit themselves, in such a way that, over all cycles of the part of the cycles, a first value of the upper voltage limit is almost never exceeded and a second value of the lower voltage limit is almost never undershot,
c) forming a generated measurement data set for the part of the cycles in such a way that modified at least partially correlating parameters of the manipulated part of the measurement data and the unmanipulated part of the measurement data from the part of the cycles are merged,
d) generating signals representing the values of the generated measurement data for processing using the HPC method,
e) determining the aging on the basis of the processing of at least the signals representing the values of the generated measurement data.

With the method according to embodiments of the invention, manipulated signals are generated from signals for measurement data from a cycling process and can be used by the high-precision coulometry, HPC, method, even if these signals originate from measurement data from a cycling process which were not generated according to the HPC method or its framework conditions for a cycling process.

The apparatus according to embodiments of the invention comprises means for carrying out the method according to embodiments of the invention or one of the preferred configurations and developments of the method, in particular at least one module for carrying out the method.

The computer program product (non-transitory computer readable storage medium having instructions, which when executed by a processor, perform actions) according to embodiments of the invention is able to be loaded directly into a memory of a programmable computing unit, containing program code means for carrying out the method according to embodiments of the invention or one of the preferred configurations and developments of the method when the computer program product is executed in the computing unit.

Thus, methods and their measurements, which were not originally generated for this purpose and thus initially do not have the required accuracy at the beginning of the method according to embodiments of the invention, can also be used within the scope of the method according to embodiments of the invention to determine the aging rate of batteries using the HPC method.

In one development of the method according to embodiments of the invention, the part of the measurement data is branched from the measurement data formed by the parameters measured over the cycles in such a way that a part of the measurement data formed by the parameters measured over the cycles, which precedes the part in terms of time, in particular fluctuates greatly in terms of its values due to a transient condition with respect to at least one of the parameters, is excluded.

This assists embodiments of the invention in being able to form the usable voltage window to be as large as possible, because the temporally preceding part of the recorded measurement data from the cycling process, for example the first half or the first two thirds, can usually be discarded. In the first part of the measurement data, which is cut off here, the cell of a battery storage device is usually in a transient response, with the result that the last part of the measurement provides the actually meaningful data. This uses embodiments of the invention in an advantageous manner and contributes to increasing the precision of the result of determining the aging rate.

It is possible to determine the values manually if the method according to embodiments of the invention is developed in such a way that the first value and the second value are determined by capturing a user input.

However, these values will be generated automatically. This is achieved according to one development of the method according to embodiments of the invention, in which the first value and the second value are generated by a module performing the manipulation.

In such a module, the manipulation according to embodiments of the invention, in particular the determination of the voltage limits, can be achieved using circuitry. Circuitry solutions, which can form the module at least partially, are, for example, so-called field programmable gate arrays, as an example of an integrated circuit (IC) of digital technology, into which a logical circuit can be loaded; non-programmable gates are also conceivable. However, the module will at least partially resort to or integrate a central control device, so that at least one part of embodiments of the invention can use a computer unit. This allows a maximum degree of freedom in terms of optimizations, but also in terms of the possibilities of signal transmission and/or processing.

In a further development of the method according to embodiments of the invention, the first value and the second value are determined in such a way that they are generated, in particular individually for each cycle, depending on the measured temperature of at least one of the cells of the battery storage device.

As a result, the method according to embodiments of the invention can also be used to compensate for adverse temperature influences, because the voltage limit for each cycle can be set individually and coupled to the measured cell temperature by means of this development. Temperature-related changes in the overvoltage can thus be compensated.

The method according to embodiments of the invention can also be developed in such a way that the determination depending on the temperature takes place at least on the basis of a dependence of the DC internal resistance of the cell on the current direction, on the SOC and/or the temperature, in particular by reading out a table reflecting this assignment.

This makes it possible to use advantageous possibilities for coupling between the voltage limit and temperature. This can be achieved in a particularly simple and advantageous manner if it is possible to generate signals by reading out measurement data stored in a structured manner, for example measurement data available by reading out a table.

Alternatively or additionally, the method according to embodiments of the invention can also be developed in such a way that, for the determination of the first value and the second value, on the basis of at least one part of the measured parameters of the cycle and/or a directly adjacent cycle, for example the amount of charge, current, time for generating, in particular on the basis of an interpolation, values that are stored as further values of the parameters of the cycle and/or a directly adjacent cycle are used.

This optimizes the signals for the HPC method; in particular, the relationship between amounts of charge and other parameters of the measurements for balancing according to the HPC method is obtained and/or used for this purpose.

A further advantageous development of the method according to embodiments of the invention is provided if the first value and/or the second value is/are determined in such a way that
a) the first and second values are determined such that, for a measured and/or manipulated maximum voltage value per charging cycle, its value per cycle is not less than the first value,
b) for a measured and/or minimum voltage value per discharge cycle, its value per cycle is not greater than the second value,
c) the number of measured and/or manipulated maximum voltage values exceeding the first value and the number of any lower voltage values undershooting the second value are reduced to a minimum.

This provides a simple but effective process for maximizing time windows for usable voltage profiles. In addition to the developments already mentioned for achieving this effect, this development also offers the advantage that hardware-related fluctuations, for example due to an excessively low resolution during the measurement, especially of the voltage values, can be eliminated.

Alternatively or additionally, the method according to embodiments of the invention can be advantageously developed in such a way that, for at least one cycle,
a1) a first past time and/or an ordinal term determining this time, in particular an index, and, for the two following times, at least one part of the measured parameters associated with the respective time, in particular determined by two following indices, in particular the amount of charge supplied to the battery storage device, is/are determined if the voltage value is above the first value in a charging cycle,
b1) the measured amount of charge assigned to the ordinal terms is taken as one of the parameters and stored in each case for charge balancing, in particular according to the HPC method,
c1) the measured parameters assigned to the ordinal terms are deleted,
d1) at least two voltage values are generated and are inserted as parameters into the measured values in such a way that the first voltage value generated defines the last voltage value of the charging cycle and the second voltage value generated defines the first voltage value of the pause,
a2) a first past time and/or an ordinal term determining this time, in particular an index, and, for the two following times, at least one part of the measured parameters associated with the respective time, in particular determined by two following indices, in particular the amount of charge removed from the battery storage device, is/are determined if the voltage value is below the second value in a discharge cycle,
b2) the measured amount of charge assigned to the ordinal terms is taken as one of the parameters and stored in each case for the charge balancing, in particular according to the HPC method,
c2) the measured parameters assigned to the ordinal terms are deleted,
d2) at least two voltage values are generated and are inserted as parameters into the measured values in such a way that the first voltage value generated defines the last voltage value of the discharge cycle and the second voltage value generated defines the first voltage value of the pause.

This provides a simple and efficient process for manipulating the measurements or the measured parameters according to embodiments of the invention.

According to a further development of the method according to embodiments of the invention, the method is carried out in a computer-aided manner in a computing unit, thus resulting in maximum degrees of freedom for measurements, signal processing and/or optimization of the method.

The advantages cited with regard to the method according to embodiments of the invention and its preferred configurations and developments can be analogously applied to the apparatus according to embodiments of the invention and also lie in the fact that they allow the method to be carried out by way of their implementation.

The same also applies to the computer program product according to embodiments of the invention.

### BRIEF DESCRIPTION

Some of the embodiments will be described in detail, with reference to the following figures, wherein like designations denote like members, wherein:

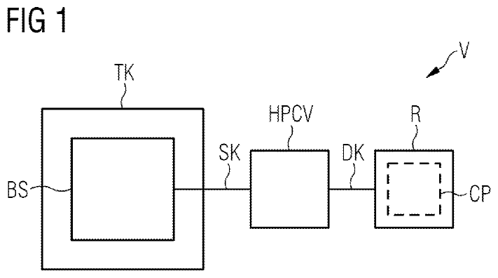

FIG. 1 schematically shows, as an exemplary embodiment of the arrangement according to embodiments of the invention, an apparatus for determining the aging of a battery storage device with a high-precision coulometry apparatus;

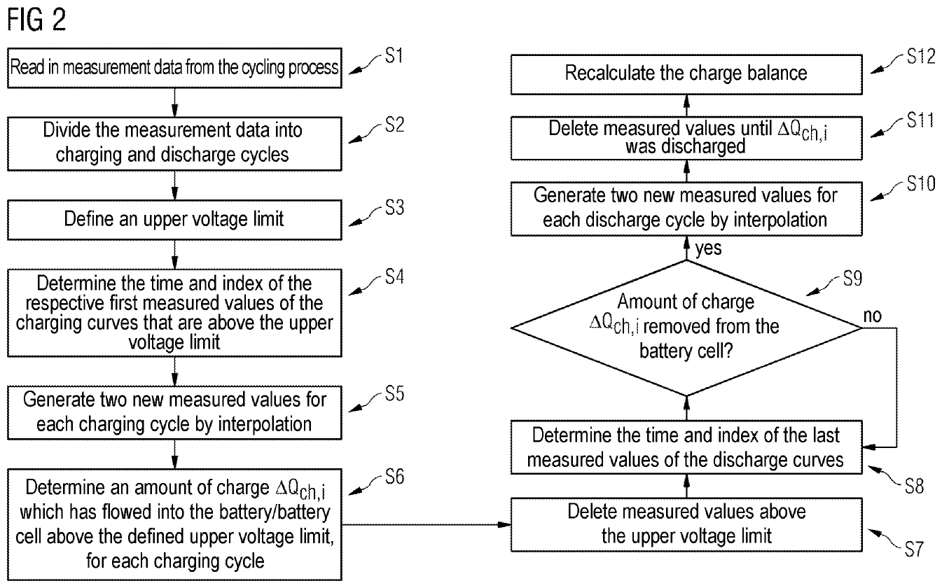

FIG. 2 schematically shows a flowchart of an exemplary embodiment of the method according to embodiments of the invention;

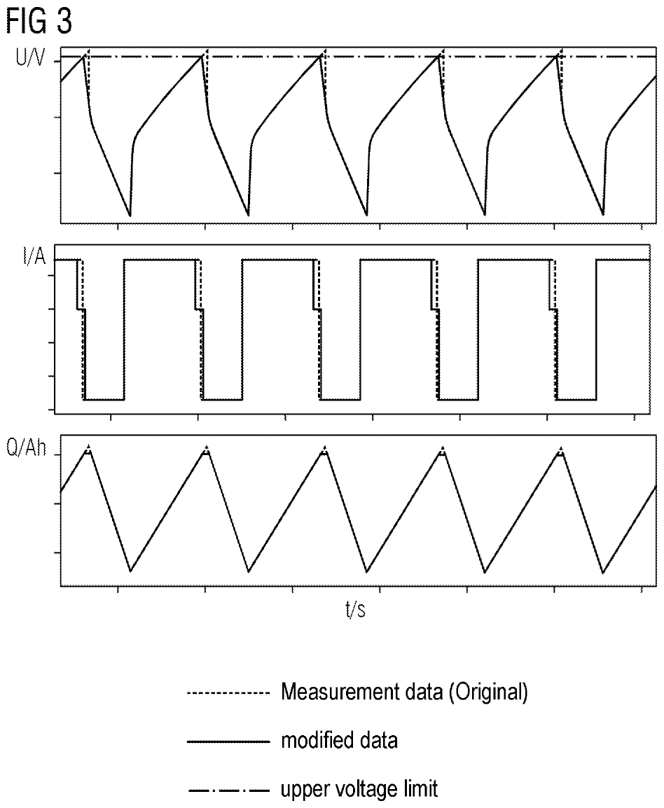

FIG. 3 shows graphs of the voltage, current and charge profiles from measurements and a schematic representation of the insertion of values when using the exemplary embodiment of the method according to embodiments of the invention;

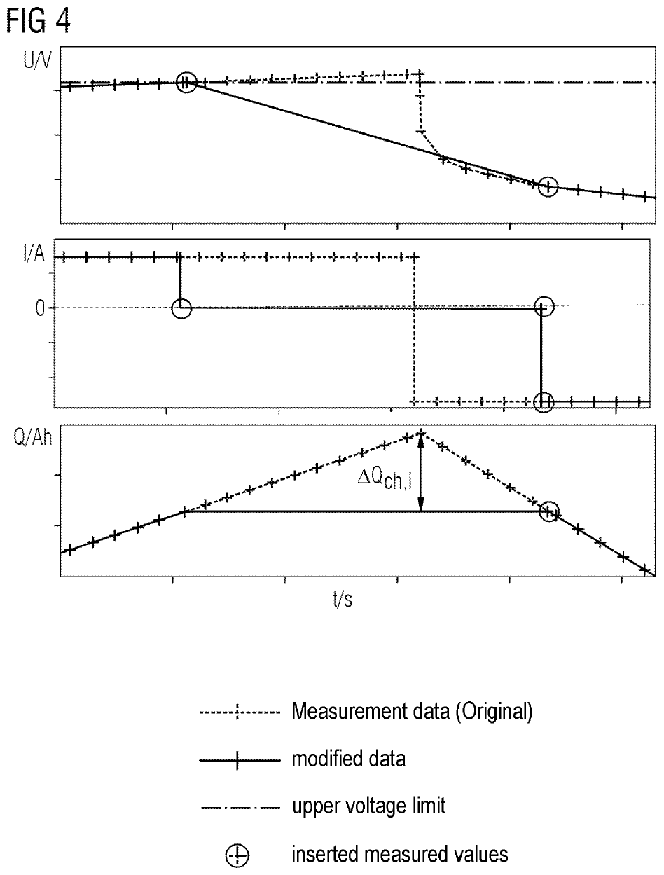

FIG. 4 shows graphs of the voltage, current and charge profiles from measurements and a schematic representation of the insertion of values, in particular the upper voltage limit and dependent values, when using the exemplary embodiment of the method according to the invention; and

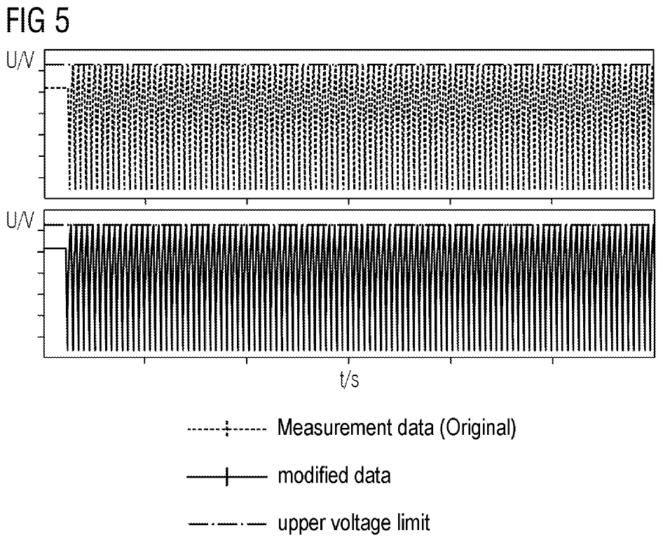

FIG. 5 shows graphs of the measured and modified voltage when using the exemplary embodiment of the method according to the invention.

### DETAILED DESCRIPTION

The exemplary embodiments explained in FIGS. 1 to 5 below are preferred embodiments and developments of embodiments of the invention.

In particular, the exemplary embodiments that follow merely show illustrative realization possibilities, how in particular such realizations of the teaching according to embodiments of the invention could be manifested, since it is impossible and also not helpful or necessary for the understanding of embodiments of the invention to name all these realization possibilities.

In the exemplary embodiments, the described components of the embodiments each represent individual features of embodiments of the invention which are to be considered independently of one another, and which each also refine embodiments of the invention independently of one another and are therefore also to be considered to be a constituent part of embodiments of the invention individually or in a combination other than that shown.

Furthermore, the described embodiments may also be supplemented by further features of embodiments of the invention that have already been described.

Identical reference signs have the same meaning in the various figures.

FIG. 1 shows a possible exemplary embodiment of the apparatus V according to embodiments of the invention for determining and setting an upper voltage limit based on the determination of measurement data using a high-precision coulometry, HPC, apparatus HPCV. The apparatus V comprises a battery storage device BS, wherein the battery storage device BS has at least one battery cell. The battery storage device BS is arranged in a temperature control chamber TK. The battery storage device BS is connected to a high-precision coulometry apparatus HPCV via a power cable SK. The high-precision coulometry apparatus HPCV is in turn connected to a computing unit R via a data cable DK. The high-precision coulometry apparatus HPCV records a charge-time graph of the battery storage device BS with a very high degree of accuracy. The battery storage device BS is cyclically charged and discharged with periodic load cycles 100. The measurement data are transmitted to the computer unit R and subjected to further processing by the latter according to a process sequence determined by a computer program product CP according to embodiments of the invention, which is installed on the computer unit R, following an exemplary embodiment of the method according to embodiments of the invention.

As an exemplary embodiment of the method according to embodiments of the invention, the sequence for setting an upper voltage limit and corresponding manipulation of measurement data is illustrated in FIG. 2 as a part of such a process sequence.

In a first step S1, the data measured according to the exemplary embodiment are read in. This are at least measurement data from a cycling process having a plurality of cycles.

It does not have to be an HPC apparatus HPCV or a cycling process in the context of an HPC method; rather, all methods mentioned at the outset, which perform a cycling process for determining battery states, are included here as long as they determine the measurement data necessary for embodiments of the invention.

Furthermore, it may be advantageous to develop this exemplary embodiment in such a way that the measurement data from the first cycles are not read in or are not used, since there can be a transient response in the first cycles, which can falsify the results of the method, in particular in the subsequent steps.

If measurement data are involved, the measurement data are divided into charging and discharge cycles according to a second method step S2.

In addition to the division, an upper voltage limit is defined in a third step S3 according to the exemplary embodiment of the method according to embodiments of the invention.

The upper voltage limit is selected in accordance with the exemplary embodiment in such a way that a consistent limit is possible over a definable measurement range that is to be analyzed and at the same time only as few measurement data as possible are above this limit.

In a fourth step S4, the time and index of the respective first measured values of the charging curves, which are above the selected, i.e. determined, upper voltage limit, are determined.

In addition, in a fifth step S5, two new measured values per charging cycle are generated by interpolation.

In this case, according to the exemplary embodiment of the method according to embodiments of the invention, the first of the two new measured values represents the last measured value of the charging cycle (current=charging current). The second new measured value represents the first measured value of the pause (current=0).

In a sixth step S6, an amount of charge ΔQch,i, which has flowed into the battery/battery cell above the defined upper voltage limit, is also determined for each charging cycle.

In accordance with a seventh step S7, the measured values above the upper voltage limit are deleted.

A further, eighth method step S8 involves determining the time and index of the last measured values of the discharge curves. This takes place as a ninth step S9 in the form of a repetition until the amount of charge ΔQch,i has been removed from the battery/battery cell.

In a tenth method step S10, two new measured values per discharge cycle are generated by interpolation. According to the exemplary embodiment of the method according to embodiments of the invention, the first of the two new measured values represents the last measured value of the discharge cycle (current=discharge current). The second new measured value represents the first measured value of the pause (current=0).

As a further, eleventh method step S11, provision is made, according to the exemplary embodiment of the method according to embodiments of the invention, for the measured values until ΔQch,i was discharged to be deleted.

In a twelfth step S12, the charge balance is then recalculated.

A lower voltage limit is set mutatis mutandis according to this exemplary embodiment of the method according to embodiments of the invention, i.e. in steps which are analogous for the inventor when considering the procedure explained above and are carried out in an interchanged or analogous manner, possibly individually adapted to the aim of determining the lower voltage limit, in particular with regard to the charging/discharge cycle and direction.

An illustration of the insertion of the upper voltage limit according to the described exemplary embodiment of the method according to embodiments of the invention is shown in FIG. 3.

In this case, the original measurement data are represented as a solid line, the upper voltage limit defined in accordance with the exemplary embodiment is represented as a dotted line and the data modified in accordance with the exemplary embodiment of the method are represented as a dot-dashed line.

The insertion is illustrated in somewhat more detail in FIG. 4. An enlarged representation for illustrating the insertion of the upper voltage limit according to the exemplary embodiment of the method according to embodiments of the invention can be seen there.

Three graphs can be seen, wherein the measured values newly inserted in accordance with the method according to embodiments of the invention from the point of intersection of the charging curve with the upper voltage limit can be seen in the uppermost, first graph, the middle, second graph shows the profile of the amount of charge ΔQch,i, as is shown when using the exemplary embodiment of the method according to embodiments of the invention, and finally the measured values newly inserted according to the exemplary embodiment of the method according to embodiments of the invention when the amount of charge ΔQch,i is undershot in the discharge curve can be seen in the lower, third graph.

The image in FIG. 5 now finally shows a comparison of the measurement data, specifically the voltage profile as would be measured with the profile that results when the upper voltage value is determined according to the exemplary embodiment of the invention. The original voltage values, which therefore do not have a constant upper voltage limit, are thus illustrated using dotted lines in the upper, first graph. This can be recognized by the fact that the voltage peaks go beyond the voltage limit determined according to embodiments of the invention—illustrated as a dot-dashed line.

The lower, second graph illustrates, with the modified voltage values (solid line) inserted according to embodiments of the invention into these original data in accordance with the exemplary embodiment of the method according to embodiments of the invention, values which are provided for the HPC method and ensure by the method according to embodiments of the invention that the defined upper voltage limit (dot-dashed line) which is also depicted is not exceeded.

A lower voltage limit is set mutatis mutandis, i.e. in an analogous and reversed manner.

Embodiments of the invention described allow a more accurate and more robust determination of battery aging rates determined by the HPC method.

The algorithm used is able to positively influence the quality of the data used. This means that data which were not originally generated for this purpose and initially do not have the required accuracy can also be used to determine the aging rate of batteries using the HPC method.

In addition, there are extensive data collections from measurement series for determining the battery aging, wherein the battery aging was determined according to the conventional method. With the conventional method, battery cells are cycled at different operating points and checkup measurements are carried out at certain intervals.

In contrast to the HPC method, the aging rates are determined from the checkup measurements and not from the cycling processes themselves. The measurement data from the cycling processes are not usually evaluated, although a lot of information about the battery aging is hidden in these data. The cycling data obtained from the conventional determination of aging rates generally do not meet the requirements of the HPC method and therefore cannot be used directly for HPC evaluations.

The aging rates are usually determined according to the conventional method (cycling and checkup alternately).

In other words, some advantages of embodiments of the invention can be listed as follows:
Embodiments of the invention describe a method and an arrangement in which the measurement data from the cycling of batteries change in such a way that the data can be used in an advantageous manner for HPC analyses. Preferred exemplary embodiments and developments of embodiments of the invention allow the voltage limits between which the battery has been cycled to be reset for evaluation.
Embodiments of the invention can be used to convert measurement data from the cycling of batteries, in which no fixed voltage limits were complied with, such that an aging rate of the battery can be determined therefrom using the HPC algorithm.
Embodiments of the invention can also be used to eliminate hardware-related fluctuations of the voltage limits, for example caused by an excessively low resolution of the voltage measurement.
Embodiments of the invention can also be used to compensate for detrimental temperature influences. Developments and exemplary embodiments of the invention in which the voltage limit is individually set for each cycle and is coupled to the measured cell temperature are appropriate in this case. Temperature-related changes in the overvoltage can thus be compensated. The coupling between the voltage limit and temperature can advantageously be carried out via a table which stores the DC internal resistance as a function of the current direction, the SOC and the temperature.
Upper and lower voltage limits can be set alternatively or additionally manually according to exemplary embodiments and developments of the invention.
However, according to exemplary embodiments and developments of the inventions, the voltage window can advantageously also be selected in such a way that it represents the largest possible voltage window, i.e. the upper voltage limit/lower voltage limit is reduced/raised only to the extent that the measurement data have common voltage limits over the area to be evaluated.
In order to be able to form the usable voltage window to be as large as possible, according to exemplary embodiments and developments of the invention, the first part of the recorded measurement data from the cycling process, for example the first half or the first two thirds, can be discarded. In the first part of the measurement data, which is cut off here, the cell is in a transient response, with the result that the last part of the measurement provides the actually meaningful data and more reliable values when determining the aging rate.

Although the present invention has been disclosed in the form of preferred embodiments and variations thereon, it will be understood that numerous additional modifications and variations could be made thereto without departing from the scope of the invention.

For the sake of clarity, it is to be understood that the use of “a” or “an” throughout this application does not exclude a plurality, and “comprising” does not exclude other steps or elements.

1. A method for determining an aging of a battery storage device by means of at least partial use of the “high-precision coulometry” (HPC) method, the method comprising:
a) running through at least two cycles of a cycling process for determining the aging of the battery storage device for the purpose of measuring parameters within the cycles in a temporally first phase;
b) manipulating measurement data formed by the parameters measured over the cycles in a second phase in such a way that at least one part of the measurement data from at least one part of the cycles is changed within the cycles with respect to parameters at least partially correlating with an upper voltage limit and a lower voltage limit in such a way that, over all cycles of the part of the cycles, a first value of the upper voltage limit is almost never exceeded and a second value of the lower voltage limit is almost never undershot;
c) forming a generated measurement data set for the part of the cycles in such a way that modified at least partially correlating parameters of the manipulated part of the measurement data and the unmanipulated part of the measurement data from the part of the cycles are merged;
d) generating signals representing the values of the generated measurement data for processing using the HPC method; and
e) determining the aging on a basis of the processing of at least the signals representing the values of the generated measurement data.

2. The method as claimed in claim 1,
wherein the part of the measurement data is branched from the measurement data formed by the parameters measured over the cycles in such a way that a part of the measurement data formed by the parameters measured over the cycles, which precedes the part in terms of time, is excluded.

3. The method as claimed in claim 2,
wherein the first value and the second value are determined by capturing a user input.

4. The method as claimed in claim 1,
wherein the first value and the second value are generated by a module performing the manipulation.

5. The method as claimed in claim 1,
wherein the first value and the second value are determined in such a way that they are generated individually for each cycle depending on the measured temperature of at least one of the cells of the battery storage device.

6. The method as claimed in claim 5,
wherein the determination depending on the temperature takes place at least on a basis of a dependence of the DC internal resistance of the cell on the current direction, on the SOC and/or the temperature, by reading out a table reflecting this assignment.

7. The method as claimed in claim 1,
wherein, for the determination of the first value and the second value, on a basis of at least one part of the measured parameters of the cycle and/or a directly adjacent cycle, values that are stored as further values of the parameters of the cycle and/or a directly adjacent cycle are used.

8. The method as claimed in claim 1,
wherein the first value and/or the second value is/are determined in such a way that:
a) the first and second values are determined such that, for a measured and/or manipulated maximum voltage value per charging cycle, its value per cycle is not less than the first value,
b) for a measured and/or minimum voltage value per discharge cycle, its value per cycle is not greater than the second value,
c) the number of measured and/or manipulated maximum voltage values exceeding the first value and the number of any lower voltage values undershooting the second value are reduced to a minimum.

9. The method as claimed in claim 1,
wherein, for at least one cycle,
a1) a first past time and/or an ordinal term determining this time, and, for the two following times, at least one part of the measured parameters associated with the respective time is/are determined if the voltage value is above the first value in a charging cycle,
b1) the measured amount of charge assigned to the ordinal terms is taken as one of the parameters and stored in each case for charge balancing, according to the HPC method,
c1) the measured parameters assigned to the ordinal terms are deleted,
d1) at least two voltage values are generated and are inserted as parameters into the measured values in such a way that the first voltage value generated defines the last voltage value of the charging cycle and the second voltage value generated defines the first voltage value of the pause,
a2) a first past time and/or an ordinal term determining this time, and, for the two following times, at least one part of the measured parameters associated with the respective time is/are determined if the voltage value is below the second value in a discharge cycle,
b2) the measured amount of charge assigned to the ordinal terms is taken as one of the parameters and stored in each case for the charge balancing, according to the HPC method,
c2) the measured parameters assigned to the ordinal terms are deleted,
d2) at least two voltage values are generated and are inserted as parameters into the measured values in such a way that the first voltage value generated defines the last voltage value of the discharge cycle and the second voltage value generated defines the first voltage value of the pause.

10. The method as claimed in claim 1,
wherein the method is carried out in a computer-aided manner in a computing unit.

11. An apparatus for carrying out the method as claimed in claim 1,
comprising means, in particular at least one module, for carrying out the method.

12. A computer program product, comprising a computer readable hardware storage device having computer readable program code stored therein, said program code executable by a processor of a computer system to implement the method as claimed in claim 1 when the computer program product is executed in the computing unit.
